(19) United States
(12) Patent Application Publication
(10) Pub. No.: US 2016/0066421 A1
(43) Pub. Date: Mar. 3, 2016

(54) SOLDER PASTE AND ELECTRONIC PART

(71) Applicant: FUJITSU LIMITED, Kawasaki-shi (JP)

(72) Inventors: Kazuhiro Kitamura, Kobe (JP); Tomohisa YAGI, Takasago (JP); HIROAKI DATE, Akashi (JP); Yasuo Yamagishi, Yamato (JP)

(73) Assignee: Fujitsu Limited, Kawasaki (JP)

(21) Appl. No.: 14/832,310

(22) Filed: Aug. 21, 2015

(30) Foreign Application Priority Data
Aug. 27, 2014 (JP) 2014-172284

(51) Int. Cl. H05K 1/09; B23K 35/36; H05K 1/18; H05K 3/34; H05K 1/11; B23K 35/02; B23K 35/26

(52) U.S. Cl. CPC H05K 1/092; B23K 35/025; B23K 35/3613; B23K 35/262; H05K 3/3484; H05K 1/111; H05K 1/181; H05K 2203/122; H05K 2203/0425; H05K 2203/0485; H05K 2201/0206; H05K 2201/0272

(57) ABSTRACT

A solder paste includes: solder particles containing Sn and Bi; an epoxy resin having two or more epoxy groups; an epoxy compound having one epoxy group; and a curing agent.

And an electronic part includes: a wiring board provided with an electrode pad; a part mounted on the wiring board and provided with a plurality of electrodes; and a cured product of a solder paste configured to connect the plurality of electrodes and the electrode pad, wherein the solder paste includes: solder particles containing Sn and Bi; an epoxy resin having two or more epoxy groups; an epoxy compound having one epoxy group; and a curing agent.

### CROSS-REFERENCE TO RELATED APPLICATION

This application is based upon and claims the benefit of priority of the prior Japanese Patent Application No. 2014-172284 filed on Aug. 27, 2014, the entire contents of which are incorporated herein by reference.

### FIELD

The embodiments discussed herein are related to a solder paste and an electronic part.

### BACKGROUND

A material known as a cream solder is used in a part mounting process. The cream solder contains solder particles and a flux component. When the cream solder is heated at a temperature above the melting point of the solder particles in a reflow furnace, the solder particles are molten and the surface oxide films of the solder particles are removed by the flux component. As a result, the solder particles are integrated. As such, conduction between a board and a part is secured.

Conventionally, a Sn—Ag—Cu-based material has been widely used for the solder particles of the cream solder. However, when the Sn—Ag—Cu-based material is used, the reflow temperature is about 240° C. that is high. Therefore, there are problems of thermal degradation of a mounted part having low heat resistance, and adhesion failure of the solder caused by warpage of a composite member such as a printed circuit board.

As a material reflow able at a low temperature, a Sn—Bi eutectic solder has been considered for a long time and its practical use is also continuously tried. However, in the Sn—Bi eutectic solder, there is concern about weakness against mechanical impact because of vulnerability of Bi and thermal fatigue resistance. In order to compensate for the vulnerability of the mechanical strength, a material has been considered, in which an epoxy resin having a flux function is used in place of a conventional rosin flux and the epoxy resin is thermally cured during the reflow. That is, the impact resistance and the fatigue facture of the Sn—Bi eutectic solder may be improved by reinforcing the vicinity of a junction with the thermally cured epoxy resin.

However, when the epoxy resin-containing solder paste is used, the junction is covered with the thermosetting epoxy resin. For this reason, a repair cannot be performed with a soldering iron, and it is thus difficult to restore the positional displacement of a part after mounting or to remove a part from a printed circuit board which has been returned by a failure.

The following are reference documents.
[Document 1] Japanese National Publication of International Patent Application No. 2002-514973,
[Document 2] Japanese Laid-Open Patent Publication No. 2001-170797, and
[Document 3] Japanese Patent No. 4897932.

### SUMMARY

According to an aspect of the invention, a solder paste includes: solder particles containing Sn and Bi; an epoxy resin having two or more epoxy groups; an epoxy compound having one epoxy group; and a curing agent.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a photograph of an electrode portion covered with a solder during the evaluation of repair ability in Example 1;

FIG. 1B is a photograph of the electrode portion after a touch-up with a soldering iron during the evaluation of repair ability in Example 1;

FIG. 2A is a cross-sectional SEM photograph of the electrode portion after the touch-up during the evaluation of repair ability in Example 1; and

FIG. 2B is an enlarged photograph of the surrounding portion in FIG. 2A.

FIG. 3 is an evaluation result of the solder aggregation of the solder after reflowing the solder on the board.

### DESCRIPTION OF EMBODIMENTS

(Solder Paste)

A solder paste of the present disclosure includes essentially solder particles, an epoxy resin having two or more epoxy groups, an epoxy compound having one epoxy group, and a curing agent. The solder paste further other components as needed.

In the following description, the generic term of components other than the solder particles in the solder paste may be referred to as a flux.

<Solder Particles>
The solder particles contain Sn and Bi.
The content of Bi in the solder particles may be appropriately selected depending on the purpose without being particularly limited. The content of Bi in the solder particles may be 45% by mass to 64% by mass.

The solder particles may contain Sb. By containing Sb, the solder particles are excellent in ductility. The content of Sb in the solder particles may be 0.3% by mass to 0.8% by mass.

The solder particles may contain 45% by mass to 64% by mass of Bi and the balance of Sn and inevitable impurities.

Further, the solder particles may contain 45% by mass to 64% by mass of Bi, 0.3% by mass to 0.8% by mass of Sb, and the balance of Sn and inevitable impurities.

The melting point of the solder particles may be appropriately selected depending on the purpose without being particularly limited. The melting point of the solder particles may be 130° C. to 150° C.

The size of the solder particles may be appropriately selected depending on the purpose without being particularly limited.

The content of the soldering particles in the solder paste may be appropriately selected depending on the purpose without being particularly limited. The content of the soldering particles in the solder paste may be 60% by mass to 95% by mass, 70% by mass to 93% by mass, or 80% by mass to 90% by mass.

<Epoxy Resin Having Two or More Epoxy Groups>
The epoxy resin having two or more epoxy groups may be appropriately selected depending on the purpose without being particularly limited. The epoxy resin may be an aromatic epoxy resin. Examples of the aromatic epoxy resin may include a bisphenol type epoxy resin, a biphenyl type epoxy resin, and a naphthalene type epoxy resin. Examples of the bisphenol type epoxy resin may include a bisphenol A type epoxy resin, a bisphenol F type epoxy resin, and a bisphenol S type epoxy resin.

The epoxy resin having two or more epoxy groups may be used either alone or in combination of two or more kinds thereof. However, the epoxy resin may be preferably used in combination of two or more kinds thereof.

The number of epoxy groups in the epoxy resin having two or more epoxy groups may be 2.

The content of the epoxy resin having two or more epoxy groups in the solder paste may be appropriately selected depending on the purpose without being particularly limited. The content of the epoxy resin having two or more groups may be 1.0% by mass to 10% by mass, 2.0% by mass to 8.0% by mass, or 3.0% by mass to 7.0% by mass.

<Epoxy Compound Having One Epoxy Group>
The epoxy compound having one epoxy group may be selected appropriately depending on the purpose without being particularly limited. The epoxy component having one epoxy group may be a compound having a glycidyl ether group.

The compound having a glycidyl ether group may be allyl glycidyl ether or a compound represented by Formula (1) below:

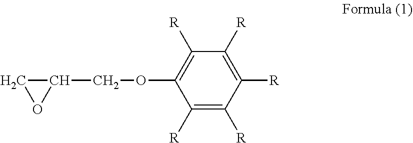

In Formula (1), each R independently represents a hydrogen atom, a halogen atom, or an alkyl group having 1 to 6 carbon atoms.

Examples of the alkyl group having 1 to 6 carbon atoms as R may include a methyl group, an ethyl group, a n-propyl group, an iso-propyl group, a n-butyl group, a sec-butyl group, a tert-butyl group, a n-pentyl group, and a n-hexyl group.

Examples of the halogen atom as R may include a fluorine atom, a chlorine atom, and a bromine atom. Among those, a bromine atom is preferred.

The compound represented by Formula (1) may be phenyl glycidyl ether, methylphenyl glycidyl ether, a tert-butylphenyl glycidyl ether, and dibromophenyl glycidyl ether.

Examples of the methylphenyl glycidyl ether may include 4-methylphenyl glycidyl ether.

Examples of the tert-butylphenyl glycidyl ether may include 4-tert-butylphenyl glycidyl ether.

Examples of the dibromophenyl glycidyl ether may include 2,4-dibromophenyl glycidyl ether.

Phenyl glycidyl ether is particularly preferred as the compound having a glycidyl ether group in that the solder particles hardly leak out during bonding due to its high volatility.

The molecular weight of the epoxy compound having one epoxy group may be appropriately selected depending on the purpose without being particularly limited. The molecular weight of the epoxy compound may be 300 or less, or 250 or less.

The content of the epoxy compound having one epoxy group in the solder paste may be appropriately selected depending on the purpose without being particularly limited. The content of the epoxy compound may be 0.5% by mass to 5.0% by mass, 1.0% by mass to 4.0% by mass, or 1.5% by mass to 2.5% by mass.

The content of the epoxy compound having one epoxy group may be 20% by mass to 60% by mass, 30% by mass to 50% by mass, or 35% by mass to 45% by mas based on the epoxy resin having two or more epoxy group.

<Curing Agent>
The curing agent may be appropriately selected depending on the purpose without being particularly limited, and examples thereof may include organic acid, an amine compound, organic acid dihydrazide, a phosphorus-based compound, a phenol resin, an acid anhydride, and an imidazole-based curing agent.

The curing agent may be used either alone or in combination of two or more kinds thereof.

Among those, organic acid or acid anhydride may be preferred in terms of proper reactivity. The organic acid is effective in cleaning the oxide film of the solder particle surface and preventing re-oxidation.

—Organic Acid—
The organic acid may be divalent carboxylic acid, and may be dicarboxylic acid. The dicarboxylic acid may be a compound represented by Formula (2) below:

HOOC—R—COOH Formula (2)

In Formula (2), R represents a divalent hydrocarbon having 1 to 20 carbon atoms.

R may be a divalent hydrocarbon having 1 to 10 carbon atoms, and may be a straight alkylene group having 2 to 10 carbon atoms.

Examples of the dicarboxylic acid may include citric acid, glutaric acid, adipic acid, sebacic acid, maleic acid, and succinic acid.

—Acid Anhydride—
Examples of the acid anhydride may include phthalic anhydride, tetrahydrophthalic anhydride, and hexahyrophthalic anhydride. They may have a substituent on their ring structures.

Examples of the substituent may include a methyl group and an ethyl group.

Examples of such acid anhydride may include 3-methyltetrahydrophthalic anhydride, 4-methyltetrahydrophthalic anhydride, 3-ethyltetrahydrophthalic anhydride, 4-ethyltetrahydrophthalic anhydride, 3-methylhexahydrophthalic anhydride, 4-methylhexahydrophthalic anhydride, 3-ethylhexahydrophthalic anhydride, and 4-ethylhexahydrophthalic anhydride.

The content of the curing agent in the solder paste may be appropriately selected depending on the purpose without being particularly limited. The content of the curing agent in the solder paste may be 2.0% by mass to 10% by mass, 3.0% by mass to 9.0% by mass, or 4.0% by mass to 8.0% by mass.

<Other Components>
The other components may be appropriately selected depending on the purpose without being particularly limited, and examples thereof may include a silane coupling agent, and a thixotropic agent.

<<Silane Coupling Agent>>
The silane coupling agent may be appropriately selected depending on the purpose without being particularly limited, and examples thereof may include 3-mercaptopropyltrimethoxysilane, 3-mercaptopropyltriethoxysilane, 3-glycidoxypropyltrimethoxysilane, and 3-glycidoxypropyltriethoxysilane. Further, 3-glycidoxypropyltrimethoxysilane and 3-glycidoxypropyltriethoxysilane also correspond to the epoxy compound having one epoxy group.

The content of the silane coupling agent in the solder paste may be appropriately selected depending on the purpose without being particularly limited.

The content of the silane coupling agent may be 0.01% by mass to 1.0% by mass, 0.05% by mass to 0.50% by mass, or 0.10% by mass to 0.30% by mass.

—Thixotropic Agent—
The thixotropic agent may be appropriately selected depending on the purpose without being particularly limited as long as it is a thixotropic agent conventionally used in a cream solder flux, and examples thereof may include a castor oil, a hydrogenated castor oil, and a sorbitol-based thixotropic agent.

Examples of the sorbitol-based thixotropic agent may include 1,3:2,4-bis-O-(4-methylbenzylidene)-D-sorbitol.

The content of the thixotropic agent may be appropriately selected depending on the purpose without being particularly limited.

The content of the thixotropic agent may be 0.01% by mass to 1.0% by mass, 0.10% by mass to 0.60% by mass, or 0.20% by mass to 0.40% by mass.

The solder paste may be prepared by mixing a flux at least including the epoxy resin having two or more epoxy groups, the epoxy compound having one epoxy group, and the curing agent, with the solder particles.

(Electronic Part)
An electronic part of the present disclosure includes at least a wiring board, a part, and a cured product of a solder paste. The electronic part includes other members such as a terminal, as needed.

The wiring board includes an electrode pad. The part is provided with a plurality of electrodes. The cured product of the solder paste connects the plurality of electrodes and the electrode pad.

<Wiring Board>
The wiring board may be appropriately selected depending on the purpose without being particularly limited as long as it is an insulating board with an electrode pad, and examples thereof may include a ceramic board and a glass epoxy board.

The size of the wiring board may be appropriately selected depending on the purpose without being particularly limited, and examples thereof may include a board in a range of 10 mm to 200 mm in length, 10 mm to 200 mm in width, and 0.5 mm to 5 mm in thickness.

The shape of the part mounting surface of the wiring board may be appropriately selected depending on the purpose without being particularly limited, and may be, for example, square, rectangular, and circular.

<Part>
The part may be appropriately selected depending on the purpose without being particularly limited as long as it has a plurality of electrodes, and examples thereof may include a chip part and a semiconductor part.

The part is mounted on the wiring board. The chip part may be appropriately selected depending on the purpose without being particularly limited, and examples thereof may include a condenser and a resistance.

The semiconductor part may be appropriately selected depending on the purpose without being particularly limited, and examples thereof may include an integrated circuit, a large-scale integrated circuit, a transistor, a thyristor, and a diode.

They may be used either alone or in combination of two or more kinds thereof.

The size of the component may be appropriately selected depending on the purpose without being particularly limited, and examples thereof may include 1608 type (1.6 mm×0.8 mm×0.8 mm), 1005 type (1 mm×0.5 mm×0.5 mm), and 0603 type (0.6 mm×0.3 mm×0.3 mm).

In the electronic part, various kinds of parts are usually mounted on the wiring board.

Further, in the electronic part, all the parts are not necessarily solder-connected by the cured product of the solder paste. At least some of them may be solder-connected, and some of them may have a part connected to a lead frame.

<Terminal>
The terminal may be appropriately selected depending on the purpose without being particularly limited as long as it is a terminal connecting the wiring in the wiring board with an external board, and examples thereof may include a lead wire.

The electronic part may have, for example, a plurality of terminals.

The shape of the terminal may be appropriately selected depending on the purpose without being particularly limited, and examples thereof may include a wire shape.

The material of the lead wire may be appropriately selected depending on the purpose without being particularly limited, and examples thereof may include gold, silver, and copper.

The method of manufacturing the electronic part may be appropriately selected without being particularly limited, and examples thereof may include a method of applying the solder paste onto the electrode pad of the wiring board, mounting the part on the wiring board such that the electrodes of the part and the wiring pad face each other, and performing heating with a reflow furnace. By the heating with the reflow furnace, the solder particles in the solder paste are molten. Then, the flux in the solder paste is cured and at the same time, the electrode pad and the electrodes are electrically connected with each other.

The heating temperature with the reflow furnace may be appropriately selected without being particularly limited, and may be, for example, 150° C. to 200° C. as a reaching temperature.

The heating time with the reflow furnace may be appropriately selected without being particularly limited, and may be, for example, 2 hours to 4 hours in the reaching temperature.

(Electronic Equipment)
Electronic equipment of the present disclosure includes at least an electronic part. The electronic equipment includes other members as needed.

The electronic part is the electronic part of the present disclosure.

Examples of the electronic equipment may include an arithmetic processor such as a personal computer and a server, communication equipment such as a portable phone and a radio device, office equipment such as a printer and a copier, AV equipment such as a television and an audio component, and home appliance such as an air conditioner and a refrigerator.

### EXAMPLES

Hereinafter, the present disclosure will be described in more detail with reference to examples, but the present disclosure is not limited to the examples at all.

### Example 1

### Preparation of Flux

After the following components A to I were weighted and mixed in a container, the mixture was roll-milled four times with three roll mills (Model 50, manufactured by Nagase Screen Printing Research Co., Ltd.) to obtain a solder paste flux. The component A and the component B were used in the state where they were heated and molten at 100° C. in advance.

[Components]

| | | |
|---|---|---|
| Component A: naphthalene type epoxy resin | 22.0 | parts by mass |
| (HP-4032D, manufactured by DIC Corporation) | | |
| Component B: bisphenol A type epoxy resin | 14.9 | parts by mass |
| (JER-1003, manufactured by Mitsubishi | | |
| Chemical Corporation) | | |
| Component C: phenyl glycidyl ether | 14.4 | parts by mass |
| (manufactured by Wako Pure Chemical | | |
| Industries Ltd.) | | |
| Component D: 3- or 4-methyl-1,2,3,6- | 24.6 | parts by mass |
| tetrahydrophthalic anhydride (trade | | |
| name: HN-2000, manufactured by Hitachi | | |
| Chemical Co., Ltd.) | | |
| Component E: | 0.5 | parts by mass |
| 3-glycidoxypropyltrimethoxysilane | | |
| (trade name: KBM-403, manufactured | | |
| by Shin-Etsu Chemical Co., Ltd.) | | |
| Component F: | 0.5 | parts by mass |
| 3-mercaptopropyltrimethoxysilane | | |
| (trade name: KBM-803, manufactured | | |
| by Shin-Etsu Chemical Co., Ltd.) | | |
| Component G: Sebacic acid (manufactured | 12.8 | parts by mass |
| by Wako Pure Chemical Industries Ltd.) | | |
| Component H: glutaric acid (manufactured by | 7.7 | parts by mass |
| Kanto Chemical Co., Inc.) | | |
| Component I: 1,3:2,4-bis-O-(4- | 2.6 | parts by mass |
| methylbenzylidene)-D-sorbitol (trade name: | | |
| gelol MD, manufactured by Shin-Nippon | | |
| Rika Co., Ltd.) | | |

<Preparation of Solder Paste>
The solder particles and the obtained solder paste flux were mixed in a mass ratio of 87:13 (solder metal particles:solder paste flux) to obtain a solder paste. The mixing was first performed using a kneading mixer (f model. 03, manufactured by PRIMIX Corporation) for 30 minutes. Subsequently, the mixing was performed using a paste mixer (UM102, manufactured by Japan Unix Co., Ltd.) for 10 seconds.

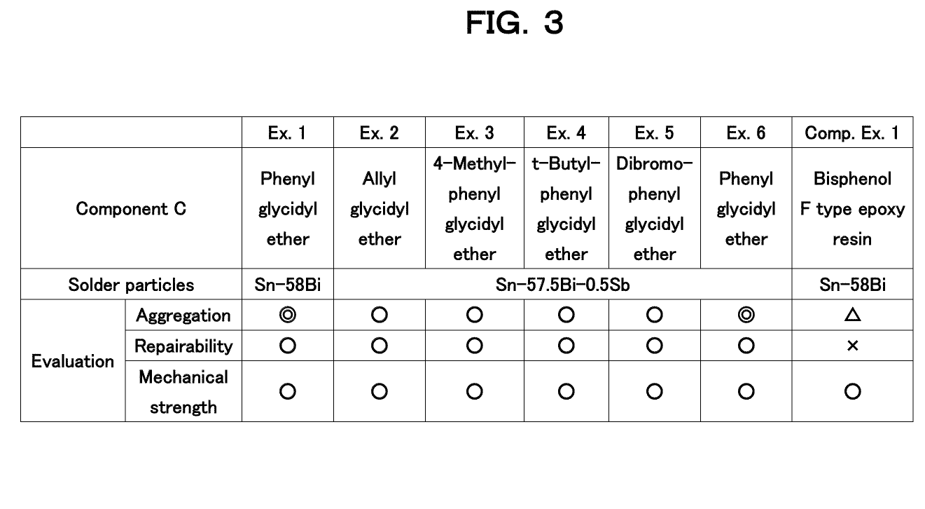

Further, as for the solder particles, Sn-58Bi (an alloy composed of 42% by mass of Sn and 58% by mass of Bi. Diameter 0.25 mm) was used.

<Solder Aggregation>
The obtained solder paste was reflow-heated as it is without mounting any chip part on a printed mounting board. Then, the solder aggregation was evaluated. The solder (particles) is molten during the reflow and becomes one large sphere on an electrode. When the aggregation of the solder is insufficient, non-aggregated solder balls are generated around the electrode. The phenomenon was observed and evaluated by the following evaluation criteria. The result is represented in FIG. 3.

The conditions of the reflow-heating are as follows:

Peak top temperature of the reflow: 180° C.

Retention time of the peak top temperature: about 3 minutes

Temperature increase rate from 100° C. to 180° C.: about 1° C./sec

Further, as the mounting board, a Ni/Au flash plating evaluation substrate of a Cu electrode was used. The size of the substrate is 130 mm×60 mm, and the thickness of the substrate is 0.7 mm.

[Evaluation Criteria]

⊚: No non-aggregated solder ball exists around the electrode

◯: One to three non-aggregated solder balls exist around the electrode

Δ: Four or more non-aggregated solder balls exist around the electrode

<Confirmation of Repair Ability by Soldering Iron>
As for the printed board reflow-mounted at the peak top temperature of 180° C. using an electrode pad covered with the solder, the repair ability by a soldering iron was confirmed.

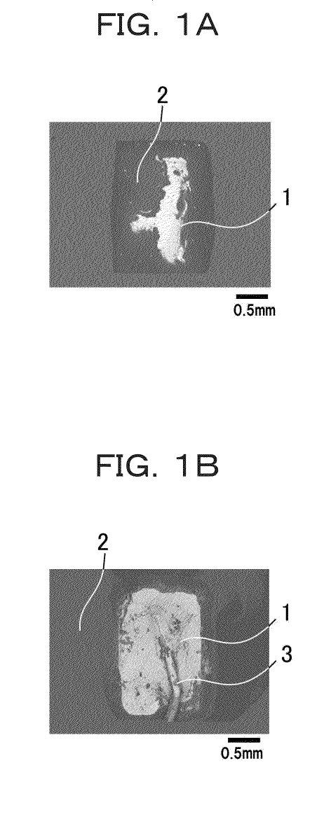

The electrode pad is a 10 mm×15 mm copper electrode portion which is reflow-heated without mounting a chip part (FIG. 1A). The electrode pad was soldered using a Sn—Bi solder as a copper wire having a diameter of 0.15 mm (Sn—Bi was pre-soldered in advance). The soldering iron was RX-802AS manufactured by Taiyo Electric Industry Co., Ltd., and the iron tip temperature was set to 250° C.

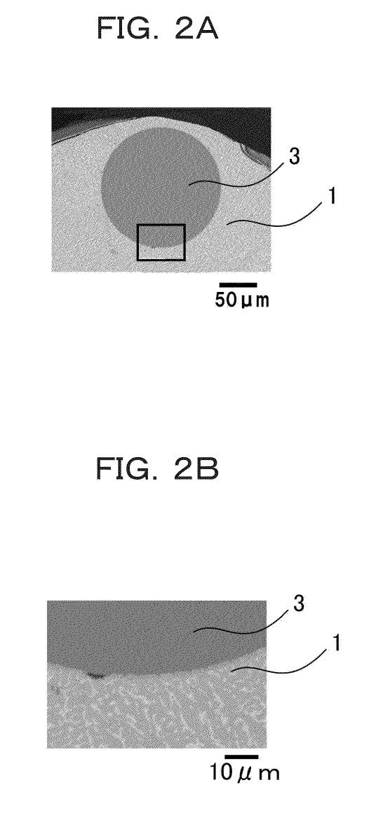

The appearance photograph of a touch-up portion is illustrated in FIG. 1B. A cross-sectional SEM photograph is illustrated in FIG. 2A. Further, an enlarged photograph of the surrounding portion is illustrated in FIG. 2B.

In FIG. 1A, the white part is Sn—Bi (reference numeral 1), and black part is a portion covered with an adhesive 2 (flux).

The electrode portion before the soldering iron is touched (FIG. 1A) is covered with the cured adhesive 2 (flux). However, when the soldering iron is touched, the heated adhesive 2 is molten and flows out around the electrode portion, so that the copper wire 3 can be soldered at the same time (FIG. 1B). As can be seen from FIGS. 2A and 2B, the adhesive 2 phase does not exist in the interface between the copper wire 3 and Sn—Bi (reference numeral 1), both of which form a metallic bond.

And, the repair ability was evaluated by the following evaluation criteria. The result is represented in FIG. 3.

[Evaluation Criteria]

◯: Soldering is possible

X: Soldering is impossible

<Mechanical Strength>
The shear strength of the solder ball was measured. Specifically, a force was applied to a predetermined position of a solder bump of a test specimen in a direction orthogonal to the thickness direction of the chip component to measure strength (g) when the solder bump is torn off. The measuring apparatus was a multipurpose bond tester series 4000 manufactured by Dage Japan Co., Ltd. The mask height was set to 100 μm, the test height was set to 100 μm, and the shear rate was set to 250 μm/s.

The test specimen was fabricated as follows. An electrode pad composed of a Cu/Sn plating (Sn film thickness of 0.5 μm) was formed at a position where a chip part on a single-sided plate with a thickness of 1.6 mm was mounted. The solder paste was printed on the electrode pad. The chip part (2012) was loaded on the electrode pad and reflow-mounted at the peak top temperature of 180° C.

The result of a commercially available Sn—Bi paste (L20-LT140ZH Type 4 manufactured by Senju Metal Industry Co., Ltd.) evaluated under the same conditions was 5,600 g.

In addition, the mechanical strength was evaluated by the following evaluation criteria. The result is represented in FIG. 3.

[Evaluation Criteria]
◯: Mechanical strength equal to or higher than the mechanical strength (5,600 g) of the commercial product
X: Mechanical strength lower than the mechanical strength (5,600 g) of the commercial product

### Example 2

### Preparation of Flux

A solder paste flux was obtained in the same manner as in Example 1, except that the component C in the preparation of the flux of Example 1 was changed to 14.4 parts by mass of allyl glycidyl ether (manufactured by Wako Pure Chemical Industries Ltd.).

<Preparation of Solder Paste>
The solder particles and the obtained solder paste flux were mixed in a mass ratio of 87:13 (solder metal particles:solder paste flux) to obtain a solder paste. The mixing was first performed using a kneading mixer (f model. 03, manufactured by PRIMIX Corporation) for 30 minutes. Subsequently, the mixing was performed using a paste mixer (UM102, manufactured by Japan Unix Co., Ltd.) for 10 seconds.

Further, as for the solder particles, Sn-57.5Bi-0.5Sb (an alloy composed of 42% by mass of Sn, 57.5% by mass of Bi, and 0.5% by mass of Sb: Type 4 (20 μm to 38 μm) was used.

The obtained solder paste was subjected to the same evaluation as in Example 1. The result is represented in FIG. 3.

### Example 3

### Preparation of Flux

A solder paste flux was obtained in the same manner as in Example 1, except that the component C in the preparation of the flux of Example 1 was changed to 14.4 parts by mass of 4-methylphenyl glycidyl ether (ED-509S, manufactured by Adeka Corporation).

<Preparation of Solder Paste>
The solder particles and the obtained solder paste flux were mixed in a mass ratio of 87:13 (solder metal particles:solder paste flux) to obtain a solder paste. The mixing was first performed using a kneading mixer (f model. 03, manufactured by PRIMIX Corporation) for 30 minutes. Subsequently, the mixing was performed using a paste mixer (UM102, manufactured by Japan Unix Co., Ltd.) for 10 seconds.

Further, as for the solder particles, Sn-57.5Bi-0.5Sb (an alloy composed of 42% by mass of Sn, 57.5% by mass of Bi, and 0.5% by mass of Sb: Type 4 (20 μm to 38 μm) was used.

The obtained solder paste was subjected to the same evaluation as in Example 1. The result is represented in FIG. 3.

### Example 4

### Preparation of Flux

A solder paste flux was obtained in the same manner as in Example 1, except that the component C in the preparation of the flux of Example 1 was changed to 14.4 parts by mass of tert-butylphenyl glycidyl ether (ED-509S, manufactured by Adeka Corporation).

<Preparation of Solder Paste>
The solder particles and the obtained solder paste flux were mixed in a mass ratio of 87:13 (solder metal particles:solder paste flux) to obtain a solder paste. The mixing was first performed using a kneading mixer (f model. 03, manufactured by PRIMIX Corporation) for 30 minutes. Subsequently, the mixing was performed using a paste mixer (UM102, manufactured by Japan Unix Co., Ltd.) for 10 seconds.

Further, as for the solder particles, Sn-57.5Bi-0.5Sb (an alloy composed of 42% by mass of Sn, 57.5% by mass of Bi, and 0.5% by mass of Sb: Type 4 (20 μm to 38 μm) was used.

The obtained solder paste was subjected to the same evaluation as in Example 1. The result is represented in FIG. 3.

### Example 5

### Preparation of Flux

A solder paste flux was obtained in the same manner as in Example 1, except that the component C in the preparation of the flux of Example 1 was changed to 14.4 parts by mass of dibromophenyl glycidyl ether (EX-147, manufactured by Nagase ChemteX Corporation).

<Preparation of Solder Paste>
The solder particles and the obtained solder paste flux were mixed in a mass ratio of 87:13 (solder metal particles:solder paste flux) to obtain a solder paste. The mixing was first performed using a kneading mixer (f model. 03, manufactured by PRIMIX Corporation) for 30 minutes. Subsequently, the mixing was performed using a paste mixer (UM102, manufactured by Japan Unix Co., Ltd.) for 10 seconds.

Further, as for the solder particles, Sn-57.5Bi-0.5Sb (an alloy composed of 42% by mass of Sn, 57.5% by mass of Bi, and 0.5% by mass of Sb: Type 4 (20 μm to 38 μm) was used.

The obtained solder paste was subjected to the same evaluation as in Example 1. The result is represented in FIG. 3.

### Example 6

### Preparation of Flux

A solder paste flux was obtained in the same manner as in Example 1, except that the component C in the preparation of the flux of Example 1 was changed to 14.4 parts by mass of phenyl glycidyl ether (manufactured by Wako Pure Chemical Industries Ltd.).

<Preparation of Solder Paste>
The solder particles and the obtained solder paste flux were mixed in a mass ratio of 87:13 (solder metal particles:solder paste flux) to obtain a solder paste. The mixing was first performed using a kneading mixer (f model. 03, manufactured by PRIMIX Corporation) for 30 minutes. Subsequently, the mixing was performed using a paste mixer (UM102, manufactured by Japan Unix Co., Ltd.) for 10 seconds.

Further, as for the solder particles, Sn-57.5Bi-0.5Sb (an alloy composed of 42% by mass of Sn, 57.5% by mass of Bi, and 0.5% by mass of Sb: Type 4 (20 μm to 38 μm) was used.

The obtained solder paste was subjected to the same evaluation as in Example 1. The result is represented in FIG. 3.

### Comparative Example 1

### Preparation of Flux

After the following components A to H were weighted and mixed in a container, the mixture was roll-milled four times with three roll mills (Model 50, manufactured by Nagase Screen Printing Research Co., Ltd.) to obtain a solder paste flux. For the component A and the component B, those heated and molten at 100° C. in advance were used.

[Components]

| | | |
|---|---|---|
| Component A: naphthalene type epoxy | 22.0 | parts by mass |
| resin (HP-4032D, manufactured | | |
| by DIC Corporation) | | |
| Component B: bisphenol A type epoxy | 14.9 | parts by mass |
| resin (JER-1003, manufactured by | | |
| Mitsubishi Chemical Corporation) | | |
| Component C: bisphenol F type epoxy | 14.4 | parts by mass |
| resin (EX-830LVP, manufactured | | |
| by DIC Corporation) | | |
| Component D: 3- or 4-methyl-1,2,3,6- | 24.6 | parts by mass |
| tetrahydrophthalic anhydride (trade | | |
| name: HN-2000, manufactured by | | |
| Hitachi Chemical Co., Ltd.) | | |
| Component E: | 1.0 | parts by mass |
| 3-mercaptopropyltrimethoxysilane | | |
| (trade name: KBM-803, manufactured | | |
| by Shin-Etsu Chemical Co., Ltd.) | | |
| Component F: Sebacic acid (manufactured by | 12.8 | parts by mass |
| Wako Pure Chemical Industries Ltd.) | | |
| Component G: glutaric acid (manufactured | 7.7 | parts by mass |
| by Kanto Chemical Co., Inc.) | | |
| Component H: 1,3:2,4-bis-O-(4- | 2.6 | parts by mass |
| methylbenzylidene)-D-sorbitol (trade name: | | |
| gelol MD, manufactured by Shin-Nippon | | |
| Rika Co., Ltd.) | | |

<Preparation of Solder Paste>
The solder particles and the obtained solder paste flux were mixed in a mass ratio of 87:13 (solder metal particles:solder paste flux) to obtain a solder paste. The mixing was first performed using a kneading mixer (f model. 03, manufactured by PRIMIX Corporation) for 30 minutes. Subsequently, the mixing was performed using a paste mixer (UM102, manufactured by Japan Unix Co., Ltd.) for 10 seconds.

Further, as for the solder particles, Sn-58Bi (an alloy composed of 42% by mass of Sn and 58% by mass of Bi. Diameter 0.25 mm) was used.

The obtained solder paste was subjected to the same evaluation as in Example 1. The result is represented in FIG. 3.

The kinds of the component C and the solder particles used in Examples 1 to 6 and Comparative Example 1 were summarized in FIG. 3.

In Examples 1 to 6 and Comparative Example 1, the mechanical strength was almost the same.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A solder paste comprising:
solder particles containing Sn and Bi;
an epoxy resin having two or more epoxy groups;
an epoxy compound having one epoxy group; and
a curing agent.

2. The solder paste according to claim 1, wherein the epoxy compound having one epoxy group is a compound having a glycidyl ether group.

3. The solder paste according to claim 2, wherein the compound having a glycidyl ether group is at least one selected from the group consisting of allyl glycidyl ether and a compound represented by Formula (1) below: 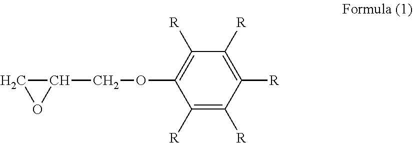
in Formula (1), each R independently represents a hydrogen atom, a halogen atom, or an alkyl group having 1 to 6 carbon atoms.

4. The solder paste according to claim 2, wherein the compound having a glycidyl ether group is at least one selected from the group consisting of allyl glycidyl ether, phenyl glycidyl ether, methylphenyl glycidyl ether, tert-butylphenyl glycidyl ether, and dibromophenyl glycidyl ether.

5. The solder paste according to claim 2, wherein the compound having a glycidyl ether group is phenyl glycidyl ether.

6. The solder paste according to claim 1, wherein a content of Bi in the particles containing Sn and Bi is 45% by mass to 65% by mass.

7. The solder paste according to claim 1, wherein a content of the epoxy compound having one epoxy group is 20% by mass to 60% by mass based on the epoxy resin having two or more epoxy groups.

8. The solder paste according to claim 1, wherein the epoxy resin having two or more epoxy groups is an aromatic epoxy resin.

9. The solder paste according to claim 1, wherein the curing agent contains at least one of organic acid and acid anhydride.

10. The solder paste according to claim 9, wherein the organic acid is dicarboxylic acid.

11. The solder paste according to claim 10, wherein the dicarboxylic acid is a compound represented by Formula (2) below:
HOOC—R—COOH Formula (2)
in Formula (2), R represents a divalent hydrocarbon group having 1 to 20 carbon atoms.

12. An electronic part comprising:
a wiring board provided with an electrode pad;
a part mounted on the wiring board and provided with a plurality of electrodes; and
a cured product of a solder paste configured to connect the plurality of electrodes and the electrode pad,
wherein the solder paste includes:
solder particles containing Sn and Bi;
an epoxy resin having two or more epoxy groups;
an epoxy compound having one epoxy group; and
a curing agent.
